(19) United States
(12) Patent Application Publication
(10) Pub. No.: US 2021/0326115 A1
(43) Pub. Date: Oct. 21, 2021

(54) SUM OF PRODUCTS CALCULATION CIRCUIT AND SUM OF PRODUCTS CALCULATION METHOD THEREOF

(71) Applicant: Igistec Co., Ltd., Hsinchu City (TW)

(72) Inventor: Tzu-Li Hung, Hsinchu City (TW)

(73) Assignee: Igistec Co., Ltd., Hsinchu City (TW)

(21) Appl. No.: 17/233,531

(22) Filed: Apr. 18, 2021

Related U.S. Application Data
(60) Provisional application No. 63/047,890, filed on Jul. 2, 2020.
(60) Provisional application No. 63/011,315, filed on Apr. 17, 2020.

(30) Foreign Application Priority Data
Mar. 24, 2021 (CN) 202110315010.4

(51) Int. Cl. G06F 7/544; H03F 3/45

(52) U.S. Cl. CPC G06F 7/5443; H03F 3/45475

(57) ABSTRACT

A sum of products calculation circuit and a sum of products calculation method thereof are provided. A first input terminal of a differential amplifier is coupled to a reference voltage. A first adjustable resistance unit and a first parallel resistance unit are connected in parallel between a second input terminal of the differential amplifier and an operating voltage. A second adjustable resistance unit and a second parallel resistance unit are connected in parallel between the second input terminal of the differential amplifier and ground. A processing circuit adjusts resistance values of the first adjustable resistance unit and the second adjustable resistance unit, and calculates a sum of the products of a first input parameter and a second input parameter according to the resistance value of the second adjustable resistance unit corresponding to a situation in which an output of the differential amplifier is in transition.

### CROSS-REFERENCE TO RELEVANT APPLICATIONS

This application claims the priority benefit of U.S. provisional application Ser. No. 63/011,315, filed on Apr. 17, 2020, U.S. provisional application Ser. No. 63/047,890, filed on Jul. 2, 2020 and China application serial no. 202110315010.4, filed on Mar. 24, 2021. The entirety of the above-mentioned patent applications are hereby incorporated by reference herein and made a part of this specification.

### BACKGROUND

### Technical Field

This disclosure relates to a calculation circuit, and in particular to a sum of products calculation circuit and a sum of products calculation method thereof.

### Description of Related Art

According to current technology, multiple pairs of coefficients have to be multiplied first to obtain multiple products, and then the multiple products are added when one wishes to add multiple products to find the sum. Therefore, in order to find the sum of products, a large number of multipliers and adders have to be used.

A conventional sum of products calculation circuit often includes multiple resistances connected in series and a transistor switch. This circuit design often has too many resistances connected in series, which results in an excessively large resistance value, and drifting of the resistance value of the transistor switch, which results in erroneous calculation results, and thus increasing the difficulty of circuit implementation.

### SUMMARY

This disclosure provides a sum of products calculation circuit and a sum of products calculation method thereof, which can greatly reduce the difficulty of circuit implementation.

A sum of products calculation circuit of the disclosure includes a differential amplifier, a first adjustable resistance unit, a first parallel resistance unit, a second adjustable resistance unit, a second parallel resistance unit, and a processing circuit. A first input terminal of the differential amplifier is coupled to a reference voltage. The first parallel resistance unit and the first adjustable resistance unit are connected in parallel between a second input terminal of the differential amplifier and an operating voltage. The second parallel resistance unit and the second adjustable resistance unit are connected in parallel between the second input terminal of the differential amplifier and ground. Resistance values of the first parallel resistance unit and the second parallel resistance unit are associated with a first input parameter and a second input parameter. The resistance value of the first adjustable resistance unit is R/(MK), and the resistance value of the second adjustable resistance unit is R/K, where R is a resistance value, M and K are positive integers, and M is greater than K. The processing circuit is coupled to the differential amplifier, the first parallel resistance unit, and the second parallel resistance unit. The processing circuit adjusts resistance values of the first adjustable resistance unit and the second adjustable resistance unit and calculates a sum of products of the first input parameter and the second input parameter according to the resistance value of the second adjustable resistance unit corresponding to a situation in which an output of the differential amplifier is in transition.

The disclosure also provides a sum of products calculation method of a sum of products calculation circuit. The sum of products calculation circuit includes a differential amplifier, a first adjustable resistance unit, a first parallel resistance unit, a second adjustable resistance unit, and a second adjustable resistance unit. A first input terminal of the differential amplifier is coupled to a reference voltage. The first adjustable resistance unit and the first parallel resistance unit are connected in parallel between a second input terminal of the differential amplifier and an operating voltage. The second adjustable resistance unit and the second parallel resistance unit are connected in parallel between the second input terminal of the differential amplifier and ground. Resistance values of the first parallel resistance unit and the second parallel resistance unit are associated with a first input parameter and a second input parameter. The resistance value of the first adjustable resistance unit is R/(MK), and the resistance value of the second adjustable resistance unit is R/K, where R is a resistance value, M and K are positive integers, and M is greater than K. The sum of products calculation method of the sum of products calculation circuit includes the following steps. The resistance values of the first adjustable resistance unit and the second adjustable resistance unit are adjusted. Whether there is a transition in an output of the differential amplifier is determined. A sum of products of the first input parameter and the second input parameter is calculated according to the resistance value of the second adjustable resistance unit corresponding to a situation in which the output of the differential amplifier is in transition.

Based on the above, the first input terminal of the differential amplifier according to the embodiment of the disclosure is coupled to the reference voltage, the first adjustable resistance unit and the first parallel resistance unit are connected in parallel between the second input terminal of the differential amplifier and the operating voltage, and the second adjustable resistance unit and the second parallel resistance unit are connected in parallel between the second input terminal of the differential amplifier and the ground, and the processing circuit adjusts the resistance values of the first adjustable resistance unit and the second adjustable resistance unit and calculates the sum of products of the first input parameter and the second input parameter according to the resistance value of the second adjustable resistance unit corresponding to the situation in which the output of the differential amplifier is in transition. Since the sum of products calculation circuit is mainly designed as a parallel resistance structure, it can effectively improve the issue of an excessively large resistance value caused by too many resistances connected in series, and can greatly reduce the difficulty of circuit implementation.

To make the abovementioned more comprehensible, several embodiments accompanied by drawings are described in detail as follows.

### BRIEF DESCRIPTION OF THE DRAWINGS

FIG. 1 is a schematic diagram of a sum of products calculation circuit according to an embodiment of the disclosure.

FIG. 2 is a schematic diagram of a sum of products calculation circuit according to another embodiment of the disclosure.

FIG. 3 is a schematic diagram of a resistor in a parallel resistance unit according to an embodiment of the disclosure.

FIG. 4 is a schematic diagram of an adjustable resistance unit according to an embodiment of the disclosure.

FIG. 5 is a schematic diagram of a sum of products calculation circuit according to another embodiment of the disclosure.

FIG. 6 is a flowchart of a sum of products calculation method of a sum of products calculation circuit according to an embodiment of the disclosure.

### DESCRIPTION OF THE EMBODIMENTS

FIG. 1 is a schematic diagram of a sum of products calculation circuit according to an embodiment of the disclosure. With reference to FIG. 1, the sum of products calculation circuit may include a differential amplifier A1, an adjustable resistance unit 102, a parallel resistance unit 104, an adjustable resistance unit 106, a parallel resistance unit 108, and a processing circuit 110. A first input terminal of the differential amplifier A1 is coupled to a reference voltage VR, the adjustable resistance unit 102 and the parallel resistance unit 104 are coupled between a second input terminal of the differential amplifier A1 and an operating voltage VC, the adjustable resistance unit 106 and the parallel resistance unit 108 are coupled between the second input terminal of the differential amplifier A1 and the ground. The parallel resistance unit 104 and the parallel resistance unit 108 may have different resistance values in response to a first input parameter x and a second input parameter w. That is, the resistance values of the parallel resistance unit 104 and the parallel resistance unit 108 are associated with the first input parameter x and the second input parameter w. The first input parameter x may, for example, include parameters x1 to xj, and the second input parameter w may, for example, include parameters w1 to wj. In an application of artificial intelligence, the parameters x1 to xj may be eigenvalue parameters, and the parameter w1 to wj may be weight parameters.

The processing circuit 110 may adjust resistance values of the adjustable resistance unit 102 and the adjustable resistance unit 106, and determine whether an output VO of the differential amplifier A1 is in transition (such as from a high voltage level to a low voltage level, or from a low voltage level to a high voltage level). Since the resistance values of the parallel resistance unit 104 and the parallel resistance unit 108 are associated with the first input parameter x and the second input parameter w, and a voltage at the second input terminal of the differential amplifier A1 is a voltage generated by dividing the operating voltage VC by the adjustable resistance unit 102, the parallel resistance unit 104, the adjustable resistance unit 106, and the parallel resistance unit 108, the processing circuit 110 may calculate a sum of products of the first input parameter x and the second input parameter w according to a proportional relationship between the resistance value of the adjustable resistance unit 106, a parallel resistance value of the adjustable resistance unit 102 and the parallel resistance unit 104, and a parallel resistance value of the adjustable resistance unit 106 and the parallel resistance unit 108 corresponding to a situation in which the output VO of the differential amplifier is in transition, through appropriately setting the resistance values of the parallel resistance unit 104 and the parallel resistance unit 108.

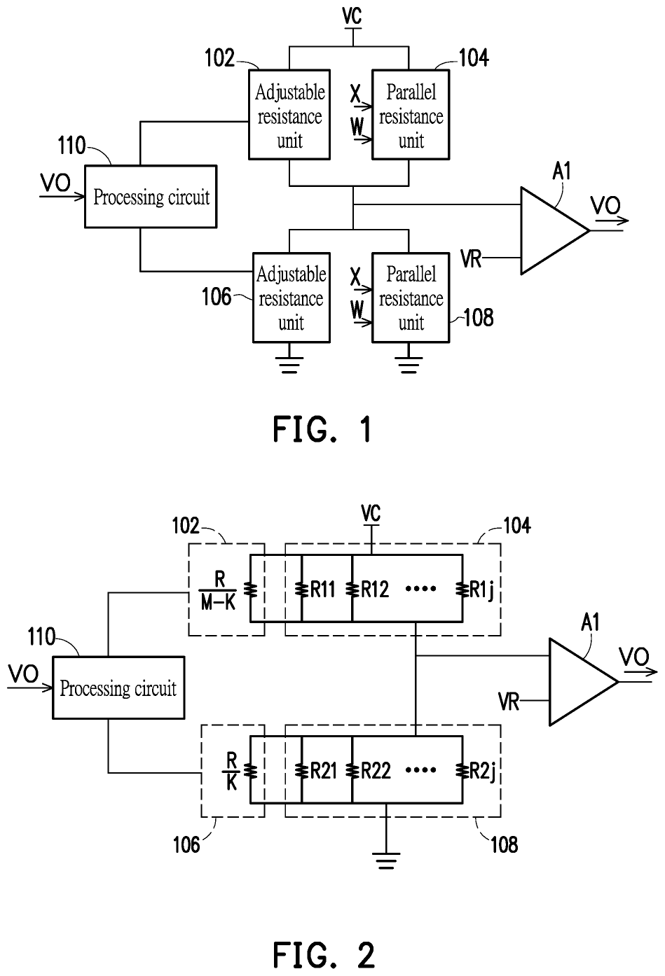

For example, FIG. 2 is a schematic diagram of an adjustable resistance unit and a parallel resistance unit in the sum of products calculation circuit according to an embodiment of the disclosure. With reference to FIG. 2, in the embodiment, the resistance value of the adjustable resistance unit 102 is R/(M−K), and the resistance value of the adjustable resistance unit 106 is R/K, where M and K are positive integers, and M is greater than K. M may be, for example, set to 255, but is not limited thereto. In the embodiment, the parallel resistance unit 104 may include multiple resistor R1n connected in parallel, and the parallel resistance unit 108 may include multiple resistor R2n connected in parallel, where n=1 to j, and j is a positive integer. In detail, each resistor R1n may include two resistors connected in series. For example, a resistor R11 may include a resistor R1 and a resistor R2 connected in series, and resistance values of the resistor R1 and the resistor R2 may be as follows.

$$\begin{matrix}R 1 = \frac{R}{\frac{1}{2} + x 1 - w 1} & ( 1 ) \\ R2 = \frac{R}{\frac{1}{2} - x 1 + w 1} & ( 2 )\end{matrix}$$

Therefore, a resistance value of the resistor R11 may be as follows.

$$R 11 = \frac{R}{\frac{1}{4} - {( x 1 - w 1 )}^{2}} \qquad ( 3 )$$

A resistance value of the nth resistor R1n, deduced by analogy, may be as follows.

$$R 1 n = \frac{R}{\frac{1}{4} - {( xn - wn )}^{2}} \qquad ( 4 )$$

Similarly, in the parallel resistance unit 108, each resistor R2n may also include two resistors connected in series. For example, a resistor R21 may include a resistor R1′ and a resistor R2′ connected in series, and resistance values of the resistor R1′ and the resistor R2′ may be as follows.

$$\begin{matrix}R {1}^{′} = \frac{R}{\frac{1}{2} + x 1 + w 1} & ( 5 ) \\ R {2}^{′} = \frac{R}{f \frac{1}{2} - x 1 - w 1} & ( 6 )\end{matrix}$$

Therefore, a resistance value of the resistor R21 may be as follows.

$$R 21 = \frac{R}{\frac{1}{4} - {( x 1 + w 1 )}^{2}} \qquad ( 7 )$$

A resistance value of the nth resistor R1n, deduced by analogy, may be as follows.

$$R 2 n = \frac{R}{\frac{1}{4} - {( xn + wn )}^{2}} \qquad ( 8 )$$

In this way, a parallel resistance value RP of the adjustable resistance unit 102 and the parallel resistance unit 104, and a parallel resistance value RS of the adjustable resistance unit 106 and the parallel resistance unit 108 may be as follows.

$$\begin{matrix}R P = \frac{R}{\frac{n}{4} - Σ {xn}^{2} - Σ {wn}^{2} - 2 + ( M - K )} & ( 9 ) \\ RS = \frac{R}{\frac{n}{4} - Σ {xn}^{2} - Σ {wn}^{2} - 2 Σ xn \cdot wn + K} & ( 10 )\end{matrix}$$

The processing circuit 110 may adjust a K value to change the resistance values RP and RS, and divide the operating voltage VC. In the embodiment, a voltage level of the reference voltage VR may be set to, for example, 0.5 times of the operating voltage VC, but it is not limited thereto. The processing circuit 110 may determine whether the output VO of the differential amplifier is in transition while adjusting the K value. When the output VO of the differential amplifier is in transition, it means that the resistance value RP is equal to the resistance value RS, and according to the equations (9) and (10), at this time, the resistance value R/K of the adjustable resistance unit 106 may be as follows.

$$\frac{R}{K} = \frac{2 R}{4 Σ xn \cdot wn + M} \qquad ( 11 )$$

Therefore, a sum of products Σxn·wn of the parameters x1 to xj and the parameters w1 to wj calculated by the processing circuit 110 may be as follows.

$$Σ xn \cdot wn = \frac{K}{2} - \frac{M}{4} \qquad ( 12 )$$

As described above, since the sum of products calculation circuit of the embodiment is mainly designed with a parallel resistance structure, it can effectively improve the issue of an excessively large resistance value caused by too many resistances connected in series, and thus, can greatly reduce the difficulty of circuit implementation.

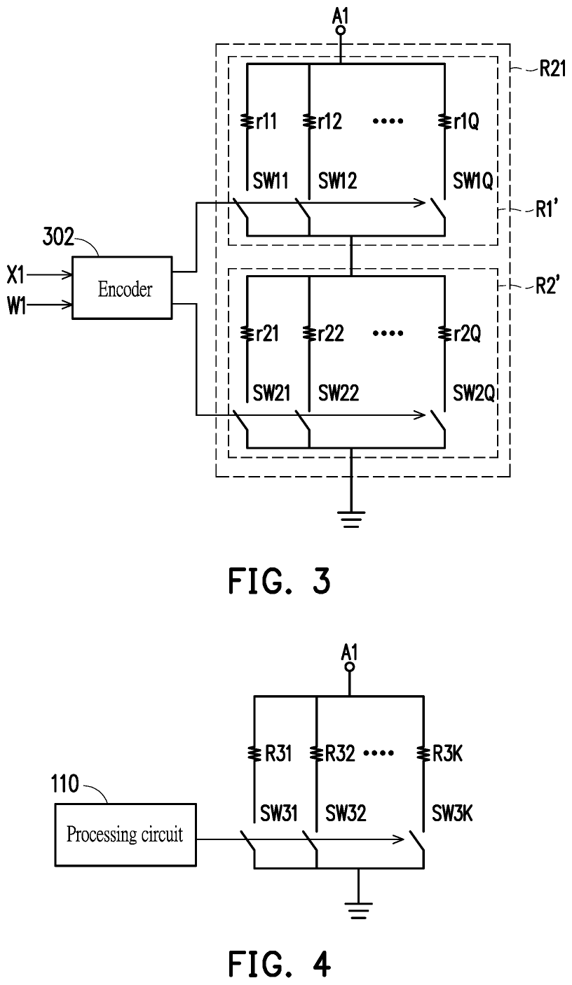

In addition, in some embodiments, the parallel resistance unit 104 and the parallel resistance unit 108 may be implemented by an encoder, multiple resistances, and multiple switches. The multiple switches may be, for example, transistor switches. FIG. 3 is a schematic diagram of a resistor of a parallel resistance unit according to an embodiment of the disclosure. Taking the resistor R21 of the parallel resistance unit 108 as an example, in the embodiment, the resistor R1′ of the resistor R21 may be implemented by resistors r11 to r1Q and switches SW11˜SW1Q, and the resistor R2′ of the resistor R21 may be implemented by resistors r21 to r2Q and switches SW21 to SW2Q, where Q is a positive integer. As shown in FIG. 3, in the resistor R1′, the resistors r11 to r1Q are respectively connected in series with the corresponding switches SW11 to SW1Q, and the multiple resistors and switches connected in series are connected in parallel to each other. In addition, in the resistor R2′, the resistors r21 to r2Q are respectively connected in series with the corresponding switches SW21 to SW2Q, and the multiple resistors and switches connected in series are connected in parallel to each other. An encoder 302 may receive the parameter x1 and the parameter w1, and control switched-on states of the switches SW11 to SW1Q and SW21 to SW2Q according to the parameter x1 and the parameter w1, to enable the resistor R21 to have a resistance value corresponding to the parameter x1 and the parameter w1 (such as the resistance value shown in equation (7)). Other resistors R22 to R2j may also, deducing by analogy, be implemented in the same manner, which will not be repeated here. In addition, the parallel resistance unit 104 may also be implemented in a manner similar to the embodiment in FIG. 3, and since those skilled in the art should be able to infer its implementation manner according to the embodiment in FIG. 3, details are not described herein.

In addition, the adjustable resistance unit 106 may also be implemented using a similar concept. As shown in FIG. 4, the adjustable resistance unit 106 may include multiple resistors R31 to R3K and multiple switches SW31 to SW3K. The resistors R31 to R3K are respectively connected in series with the corresponding switches SW31 to SW3K, and the multiple resistors and switches connected in parallel to each other. The resistors R31 to R3K respectively have a resistance value R. The processing circuit 110 may adjust the resistance value of the adjustable resistance unit 106, that is, adjust the K value, by controlling the number of the switches SW31 to SW3K that are switched on. The adjustable resistance unit 102 may also, deducing by analogy, be implemented in a manner similar to the embodiment in FIG. 4, and since those skilled in the art should be able to infer its implementation manner according to the embodiment in FIG. 4, details are not described herein again. Since the sum of products calculation circuit of the embodiment adopts a parallel resistance structure design, a required accuracy of the resistance value of the switch (such as the switches SW11 to SW1Q, SW21 to SW2Q, and SW31 to SW3K) is low. Therefore, even when the resistance value of the switch drifts due to factors such as temperature and process variation, the calculation result is not easily affected, occurrence of a calculation error in the sum of products calculation circuit can be effectively prevented.

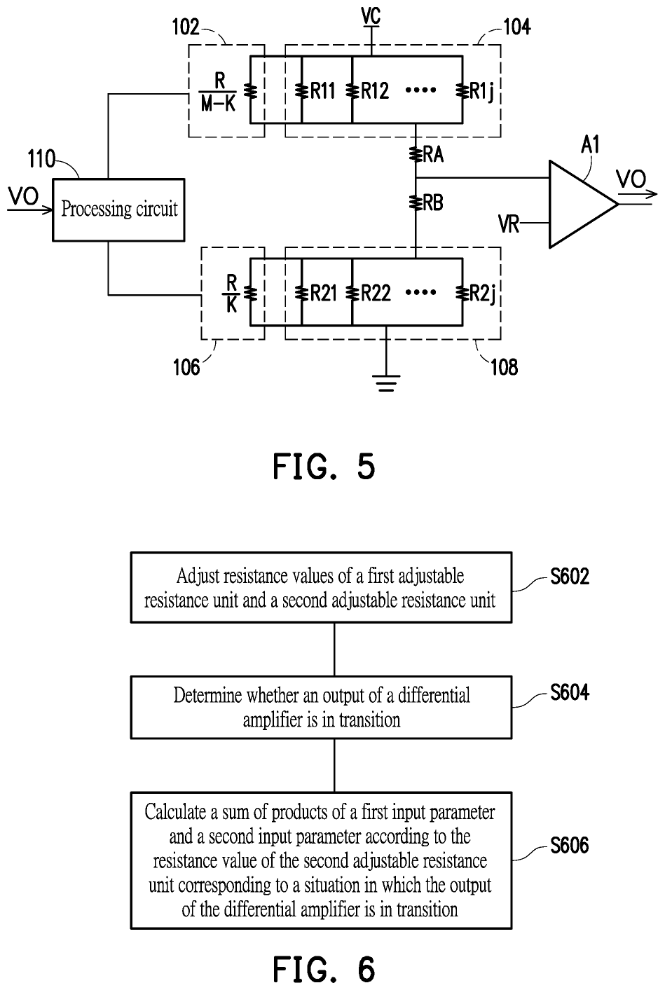

FIG. 5 is a schematic diagram of a sum of products calculation circuit according to another embodiment of the disclosure. With reference to FIG. 5, a difference between this embodiment and the embodiment in FIG. 2 is that the sum of products calculation circuit of this embodiment further includes a resistor RA and a resistor RB. One terminal of the resistor RA is coupled to the second input terminal of the differential amplifier A1, and another terminal of the resistor RA is coupled to the adjustable resistance unit 102 and the parallel resistance unit 104. One terminal of the resistor RB is coupled to the second input terminal of the differential amplifier A1, and another terminal of the resistor RB is coupled to the adjustable resistance unit 106 and the parallel resistance unit 108. Influence of resistance value fluctuation of the switches in the adjustable resistance unit 102, the parallel resistance unit 104, the adjustable resistance unit 106, and the parallel resistance unit 108 may be further reduced by the addition of the resistor RA and the resistor RB, and the occurrence of a calculation error in the sum of products calculation circuit can be prevented.

FIG. 6 is a flowchart of a sum of products calculation method of a sum of products calculation circuit according to an embodiment of the disclosure. The sum of products calculation circuit includes the differential amplifier, the first adjustable resistance unit, the first parallel resistance unit, the second adjustable resistance unit, and the second adjustable resistance unit. The first input terminal of the differential amplifier is coupled to the reference voltage. The first adjustable resistance unit and the first parallel resistance unit are connected in parallel between the second input terminal of the differential amplifier and the operating voltage. The second adjustable resistance unit and the second parallel resistance unit are connected in parallel between the second input terminal of the differential amplifier and the ground. The resistance values of the first parallel resistance unit and the second parallel resistance unit are associated with the first input parameter and the second input parameter. Furthermore, the first parallel resistance unit and the second parallel resistance unit may respectively include multiple switches, and the switches may change their switched-on state in response to the first input parameter and the second input parameter, and adjust the number of resistors connected in parallel, enabling the first parallel resistance unit and the second parallel resistance unit to be associated with the first input parameter and the second input parameter. It may be seen from the above embodiment that the sum of products calculation method of the sum of products calculation circuit may at least include the following steps. First, the resistance values of the first adjustable resistance unit and the second adjustable resistance unit are adjusted (Step S602), and then whether the output of the differential amplifier is in transition is determined (Step S604). When the output of the differential amplifier is in transition, the sum of products of the first input parameter and the second input parameter is calculated according to the resistance value of the second adjustable resistance unit corresponding to the situation in which the output of the differential amplifier is in transition (Step S606). In this way, the parallel resistance structure design can effectively improve the issue of an excessively large resistance value caused by too many resistances connected in series, and can greatly reduce the difficulty of circuit implementation.

In addition, in some embodiments, a first resistor coupled between the second input terminal of the differential amplifier and the first parallel resistance unit, and a second resistor coupled between the second input terminal of the differential amplifier and the second parallel resistance unit may be provided to further reduce the influence of the resistance value fluctuation of the switches in the first adjustable resistance unit, the first parallel resistance unit, the second adjustable resistance unit, and the second parallel resistance unit, and the occurrence of a calculation error in the sum of products calculation circuit can be further prevented.

In summary, the first input terminal of the differential amplifier according to the embodiment of the disclosure is coupled to the reference voltage, the first adjustable resistance unit and the first parallel resistance unit are connected in parallel between the second input terminal of the differential amplifier and the operating voltage, and the second adjustable resistance unit and the second parallel resistance unit are connected in parallel between the second input terminal of the differential amplifier and the ground, and the processing circuit adjusts the resistance values of the first adjustable resistance unit and the second adjustable resistance unit and calculates the sum of products of the first input parameter and the second input parameter according to the resistance value of the second adjustable resistance unit corresponding to the situation in which the output of the differential amplifier is in transition. Since the sum of products calculation circuit is mainly designed as a parallel resistance structure, it can effectively improve the issue of an excessively large resistance value caused by too many resistances connected in series, and can greatly reduce the difficulty of circuit implementation. In some embodiments, the sum of products calculation circuit may further include the first resistor coupled between the second input terminal of the differential amplifier and the first parallel resistance unit, and the second resistor coupled between the second input terminal of the differential amplifier and the second parallel resistance unit, so as to further reduce the influence of the resistance value fluctuation of the switches in the first adjustable resistance unit, the first parallel resistance unit, the second adjustable resistance unit, and the second parallel resistance unit, and further prevent the occurrence of a calculation error in the sum of products calculation circuit.

Although the disclosure has been described with reference to the above-mentioned embodiments, it is not intended to be exhaustive or to limit the disclosure to the precise form or to exemplary embodiments disclosed. It is apparent to one of ordinary skill in the art that modifications to the described embodiments may be made without departing from the spirit and the scope of the disclosure. Accordingly, the scope of the disclosure is defined by the claims appended hereto and their equivalents in which all terms are meant in their broadest reasonable sense unless otherwise indicated.

What is claimed is:

1. A sum of products calculation circuit, comprising:
a differential amplifier, wherein its first input terminal is coupled to a reference voltage;
a first adjustable resistance unit;
a first parallel resistance unit, connected in parallel to the first adjustable resistance unit between a second input terminal of the differential amplifier and an operating voltage;
a second adjustable resistance unit;
a second parallel resistance unit, connected in parallel to the second adjustable resistance unit between the second input terminal of the differential amplifier and ground, and resistance values of the first parallel resistance unit and the second parallel resistance unit are associated with a first input parameter and a second input parameter, wherein the resistance value of the first adjustable resistance unit is R/(M−K), and the resistance value of the second adjustable resistance unit is R/K, where R is a resistance value, M and K are positive integers, and M is greater than K; and
a processing circuit, coupled to the differential amplifier, the first parallel resistance unit, and the second parallel resistance unit, and the processing circuit adjusts the resistance values of the first adjustable resistance unit and the second adjustable resistance unit and calculates a sum of products of the first input parameter and the second input parameter according to the resistance value of the second adjustable resistance unit corresponding to a situation in which an output of the differential amplifier is in transition.

2. The sum of products calculation circuit according to claim 1, wherein the first parallel resistance unit comprises a plurality of resistors R1n connected in parallel, the second parallel resistance unit comprises a plurality of resistors R2n connected in parallel, the first input parameter comprises a plurality of parameters xn, and the second input parameter comprises a plurality of parameters wn, where
$$R 1 n = \frac{R}{\frac{1}{4} - {( xn - wn )}^{2}}$$
$$R2n = \frac{R}{\frac{1}{4} - {( xn + wn )}^{2}}$$

|xn|<¼, |wn|<¼, n=1 to j, and j is a positive integer.

3. The sum of products calculation circuit according to claim 2, wherein the processing circuit adjusts a K value to adjust the resistance values of the first adjustable resistance unit and the second adjustable resistance unit, and calculates the sum of products of the first input parameter and the second input parameter according to the K value corresponding to the situation in which the output of the differential amplifier is in transition.

4. The sum of products calculation circuit according to claim 1, wherein the processing circuit adjusts a K value to adjust the resistance values of the first adjustable resistance unit and the second adjustable resistance unit, and calculates the sum of products of the first input parameter and the second input parameter according to the K value corresponding to the situation in which the output of the differential amplifier is in transition.

5. The sum of products calculation circuit according to claim 1, wherein M is equal to 255.

6. The sum of products calculation circuit according to claim 1, wherein the first parallel resistance unit and the second parallel resistance unit respectively comprise a plurality of switches, and the switches change switched-on states of the switches in response to the first input parameter and the second input parameter, and adjust the number of resistors connected in parallel, so as to enable the first parallel resistance unit and the second parallel resistance unit to be associated with the first input parameter and the second input parameter.

7. The sum of products calculation circuit according to claim 6, further comprising:
a first resistor, wherein one terminal of the first resistor is coupled to the second input terminal of the differential amplifier, and another terminal of the first resistor is coupled to the first adjustable resistance unit and the first parallel resistance unit; and
a second resistor, wherein one terminal of the second resistor is coupled to the second input terminal of the differential amplifier, and another terminal of the second resistor is coupled to the second adjustable resistance unit and the second parallel resistance unit.

8. A sum of products calculation method of a sum of products calculation circuit, wherein the sum of products calculation circuit comprises a differential amplifier, a first adjustable resistance unit, a first parallel resistance unit, a second adjustable resistance unit, and a second adjustable resistance unit, a first input terminal of the differential amplifier is coupled to a reference voltage, the first adjustable resistance unit and the first parallel resistance unit are connected in parallel between a second input terminal of the differential amplifier and an operating voltage, the second adjustable resistance unit and the second parallel resistance unit are connected in parallel between the second input terminal of the differential amplifier and ground, resistance values of the first parallel resistance unit and the second parallel resistance unit are associated with a first input parameter and a second input parameter, the resistance value of the first adjustable resistance unit is R/(M−K), and the resistance value of the second adjustable resistance unit is R/K, where R is a resistance value, M and K are positive integers, and M is greater than K, the sum of products calculation method of the sum of products calculation circuit comprising:
adjusting the resistance values of the first adjustable resistance unit and the second adjustable resistance unit;
determining whether an output of the differential amplifier is in transition; and
calculating a sum of the products of the first input parameter and the second input parameter according to the resistance value of the second adjustable resistance unit corresponding to a situation in which the output of the differential amplifier is in transition.

9. The sum of products calculation method of the sum of products calculation circuit according to claim 8, wherein the first parallel resistance unit comprises a plurality of resistors R1n connected in parallel, the second parallel resistance unit comprises a plurality of resistors R2n connected in parallel, the first input parameter comprises a plurality of parameters xn, and the second input parameter comprises a plurality of parameters wn, where
$$R 1 n = \frac{R}{\frac{1}{4} - {( xn - wn )}^{2}}$$
$$R2n = \frac{R}{\frac{1}{4} - {( xn + wn )}^{2}}$$

|xn|<¼, |wn|<¼, n=1 to j, and j is a positive integer.

10. The sum of products calculation method of the sum of products calculation circuit according to claim 9, further comprising:
adjusting a K value to adjust the resistance values of the first adjustable resistance unit and the second adjustable resistance unit; and
calculating the sum of products of the first input parameter and the second input parameter according to the K value corresponding to when the output of the differential amplifier is in transition.

11. The sum of products calculation method of the sum of products calculation circuit according to claim 8, further comprising:
adjusting a K value to adjust the resistance values of the first adjustable resistance unit and the second adjustable resistance unit; and
calculating the sum of products of the first input parameter and the second input parameter according to the K value corresponding to when the output of the differential amplifier is in transition.

12. The sum of products calculation method of the sum of products calculation circuit according to claim 8, wherein the first parallel resistance unit and the second parallel resistance unit respectively comprise a plurality of switches, and the switches change switched-on states of the switches in response to the first input parameter and the second input parameter, and adjust the number of resistors connected in parallel, so as to enable the first parallel resistance unit and the second parallel resistance unit to be associated with the first input parameter and the second input parameter.
